(19) United States
(12) Patent Application Publication
(10) Pub. No.: US 2025/0210383 A1
(43) Pub. Date: Jun. 26, 2025

(54) SUBSTRATE PROCESSING APPARATUS

(71) Applicant: Samsung Electronics Co., Ltd., Suwon-si (KR)

(72) Inventors: Taehee YOO, Suwon-si (KR); Taeseung YU, Suwon-si (KR); Seongjune JEONG, Suwon-si (KR); Donghyun KO, Suwon-si (KR); Jaeho KIM, Suwon-si (KR)

(73) Assignee: Samsung Electronics Co., Ltd., Suwon-si (KR)

(21) Appl. No.: 18/758,486

(22) Filed: Jun. 28, 2024

(30) Foreign Application Priority Data
Dec. 21, 2023 (KR) 10-2023-0188649

(51) Int. Cl. H01L 21/67; H01L 21/687

(52) U.S. Cl. CPC H01L 21/67167; H01L 21/67017; H01L 21/68707

(57) ABSTRACT

Provided are a process module and a substrate processing apparatus including the same. The process module includes a plurality of process chambers each including a processing space in which a plurality of substrates are processed and a plurality of processing areas in which the plurality of substrates are respectively arranged within the processing space, a plurality of heater blocks respectively located in the plurality of processing areas and on which the plurality of substrates are respectively arranged, a shower head arranged on each heater block and configured to spray a process gas onto each substrate, a rotating arm unit configured to receive each substrate transferred from outside each process chamber and rotate to place each substrate on each heater block, and an exhaust port formed outside each heater block and configured to suck in the process gas.

### CROSS-REFERENCE TO RELATED APPLICATION

This application is based on and claims priority under 35 U.S.C. § 119 to Korean Patent Application No. 10-2023-0188649, filed on Dec. 21, 2023, in the Korean Intellectual Property Office, the disclosure of which is incorporated by reference herein in its entirety.

### BACKGROUND

Some inventive concepts relate to a substrate processing apparatus, for example to a process module capable of processing a plurality of substrates and a substrate processing apparatus including the process module.

In a general manufacturing process of semiconductor devices, various processes, such as forming or etching a material layer on a semiconductor substrate, may be repeatedly performed. In a substrate processing apparatus configured to perform such processes, a substrate processing system configured to control a plurality of process chambers may be used. Accordingly, in such a substrate processing system, efficient control of a transfer order may be desired or required for transfer of semiconductor substrates between ones of a plurality of process chambers and between the plurality of process chambers and one or more load ports.

### SUMMARY

Some inventive concepts relate to a process module capable of simultaneously processing a plurality of substrates and a substrate processing apparatus including at least one such process module.

In addition, objectives of inventive concepts are not limited to those mentioned above, and other objectives will be clearly understood by those ordinarily skilled in the art from the following descriptions.

According to some aspects of inventive concepts, t a process module may include a plurality of process chambers, each process chamber configured to process a plurality of substrates in a processing space defined thereby; a plurality of processing areas within each processing space, the processing areas configured to have ones of the plurality of substrates respectively arranged therein; a plurality of heater blocks respectively located in the plurality of processing areas and configured to have ones of the plurality of substrates respectively arranged thereon; a shower head on each heater block, each shower head configured to spray a process gas onto at least one of the plurality of substrates; a rotating arm unit configured to receive each substrate from an outside of the process chambers and to rotate to place each substrate on each heater block; and an exhaust port outside of each heater block and configured to suck in the process gas, wherein the process chambers are respectively located in different layers.

According to some aspects of inventive concepts, a substrate processing apparatus may include a plurality of process modules, each process module comprising a plurality of process chambers arranged in different layers, each process chamber configured to process a plurality of substrates in a processing space defined thereby; a transfer module configured to transfer each substrate to or from each process module; a load lock module arranged on one side of the transfer module and configured to receive each substrate transferred to or from the transfer module; an equipment front end module arranged on one side of the load lock module and configured to keep each substrate on standby; and a load port arranged on one side of the equipment front end module and configured to have each substrate loaded therein; wherein each process chamber further comprises a head portion comprising a shower head configured to spray a process gas onto at least one substrate; a heating portion comprising a heater block and arranged in a processing area, the processing area configured to have ones of the plurality of substrates processed therein; and an exhaust portion on an outer periphery of the heater block and comprising an exhaust port configured to discharge the process gas, the processing space is of each process chamber defined between the head portion and the heating portion thereof, and a plurality of processing areas is located within each processing space.

### BRIEF DESCRIPTION OF THE DRAWINGS

Example embodiments will be more clearly understood from the following detailed description taken in conjunction with the accompanying drawings in which:

FIG. 1A is a plan view schematically illustrating a substrate processing apparatus according to some example embodiments;

FIG. 1B is a plan view schematically illustrating a substrate processing apparatus according to some example embodiments;

FIG. 2 is a perspective view schematically illustrating a process module according to some example embodiments;

FIG. 3 is a transparent perspective view schematically illustrating a process module according to some example embodiments;

FIG. 4 is an exploded perspective view schematically illustrating a process module according to some example embodiments;

FIG. 5 is a cross-sectional perspective view schematically illustrating a process module according to some example embodiments;

FIG. 6 is a cross-sectional perspective view schematically illustrating a portion of a process module according to some example embodiments;

FIG. 7 is a plan view schematically illustrating a rotating arm unit of a process module according to some example embodiments;

FIG. 8 is a plan view schematically illustrating a processing area of a process module according to some example embodiments;

FIG. 9 is a longitudinal cross-sectional view schematically illustrating a transfer module according to some example embodiments; and

FIG. 10 is a perspective view schematically illustrating a load lock module according to some example embodiments.

### DETAILED DESCRIPTION OF THE EMBODIMENTS

Hereinafter, some example embodiments will be described in detail with reference to the accompanying drawings. The same reference numerals are used for the same components in the drawings, and redundant descriptions thereof are omitted.

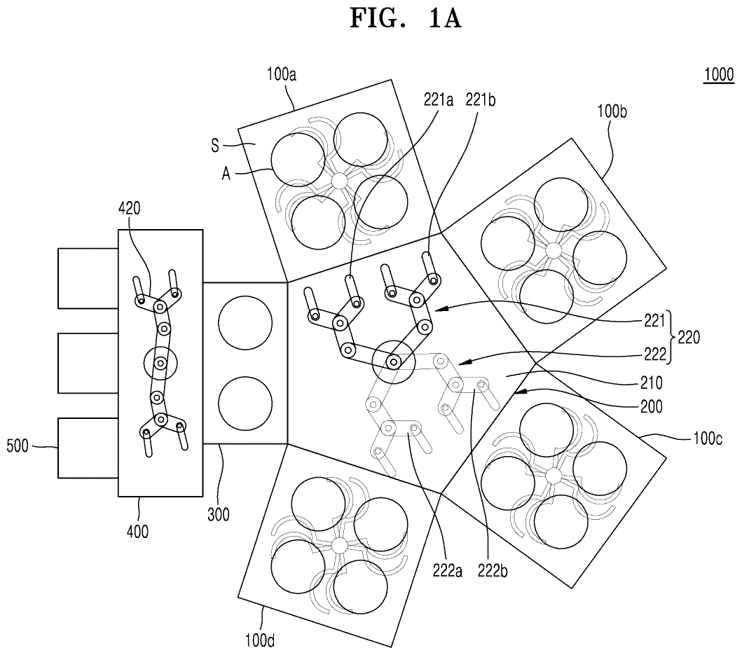

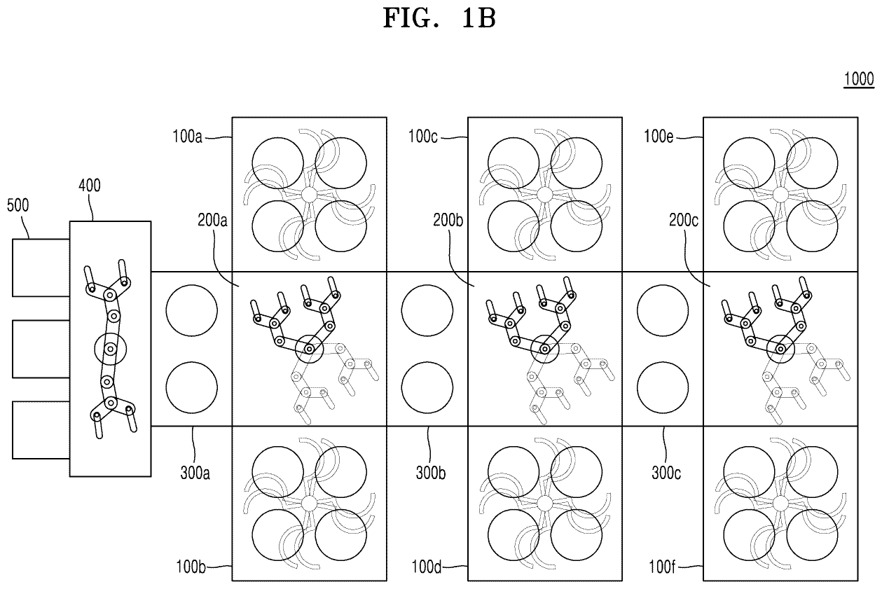

FIG. 1A is a plan view schematically illustrating a substrate processing apparatus according to some example embodiments, and FIG. 1B is a plan view schematically illustrating a substrate processing apparatus according to some example embodiments.

Referring to FIG. 1A, a substrate processing apparatus 1000 according to some example embodiments may include process modules 100a, 100b, 100c, and 100d, a transfer module 200, a load lock module 300, an equipment front end module 400, and a load port 500.

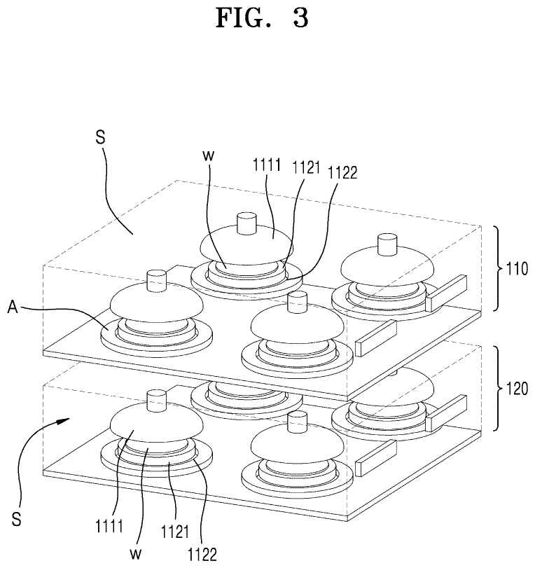

The process modules 100a, 100b, 100c, and 100d may perform (for example, be configured to perform) one or more processes for processing a substrate W (see FIG. 3), which may be provided as a plurality of substrates W. The substrate W may be transferred to the process modules 100a, 100b, 100c, and 100d through (for example, by) the transfer module 200, and the process modules 100a, 100b, 100c, and 100d may perform at least one of an etching process, a photo process, and a development process on the substrate W that has been transferred, but example embodiments are not limited thereto.

The process modules 100a, 100b, 100c, and 100d may be arranged around one transfer module 200 and outside of the transfer module 200. As shown in FIG. 1A, the process modules 100a, 100b, 100c, and 100d may be arranged to be in contact with respective sides of the transfer module 200 having a pentagonal shape. The shape of the transfer module 200 is not limited to a pentagon, and may be, for example, a polygon such as a triangle or a quadrangle, but example embodiments are not limited thereto. The process modules 100a, 100b, 100c, and 100d may be arranged to be in contact with respective sides of the transfer module 200 having a polygonal shape. For example, example embodiments as shown in FIG. 1A may be or include a cluster-type arrangement of the process modules 100a, 100b, 100c, and 100d.

In some example embodiments, referring to FIG. 1B, process modules 100a, 100b, 100c, 100d, 100e, and 100f may be arranged on multiple, for example two sides of transfer modules 200a, 200b, and 200c arranged in a row, but example embodiments are not limited thereto. For example, the transfer modules 200a, 200b, and 200c may be arranged in a row with load lock modules 300a, 300b, and 300c therebetween, and the process modules 100a, 100b, 100c, 100d, 100c, and 100f may be arranged with the transfer modules 200a, 200b, and 200c therebetween. For example, the example embodiments shown in FIG. 1B may be a track-type arrangement of the process modules 100a, 100b, 100c, 100d, 100e, and 100f.

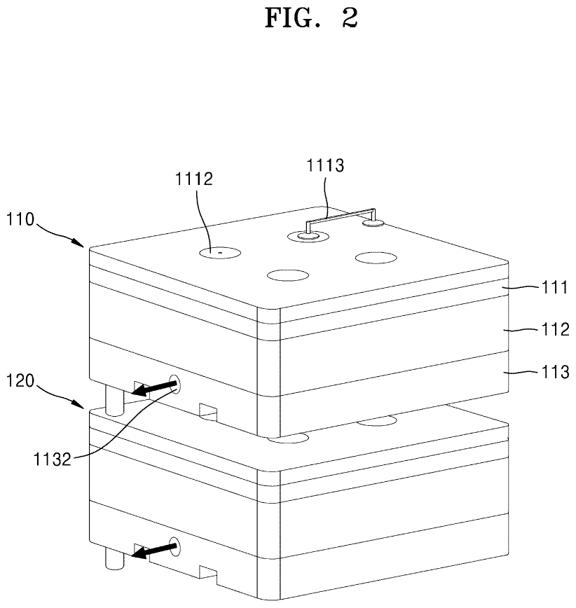

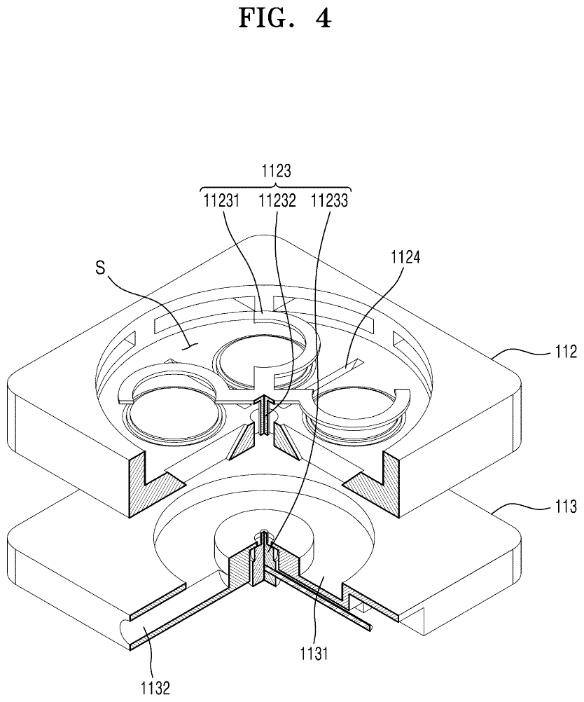

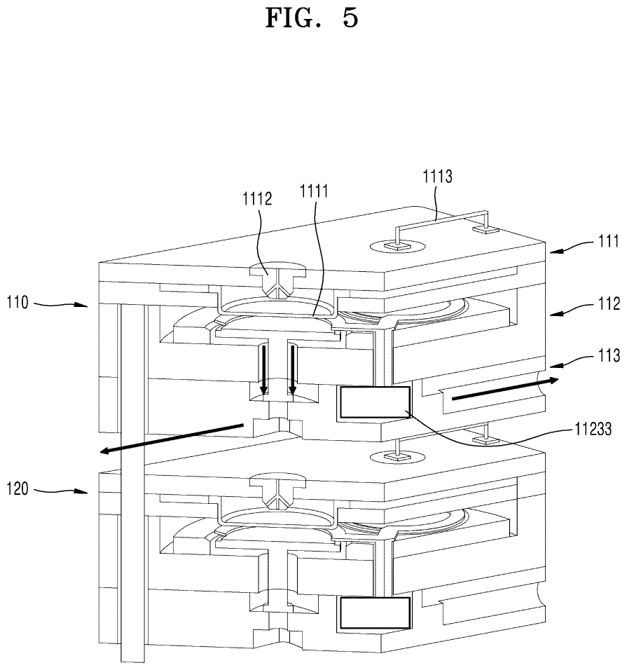

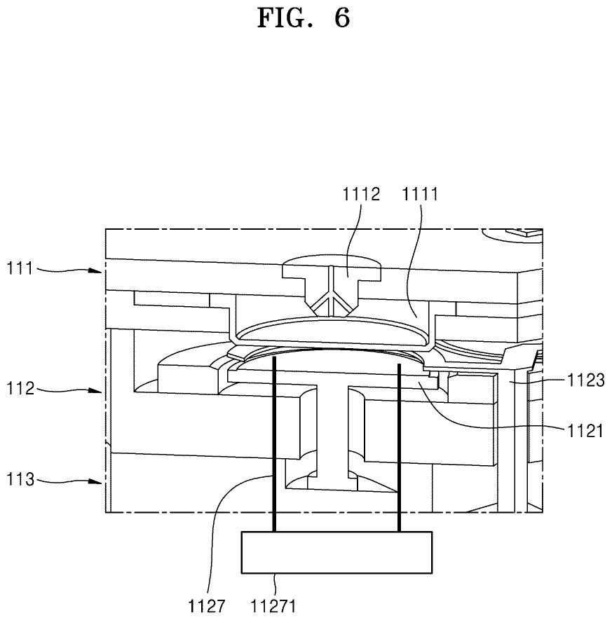

FIG. 2 is a perspective view schematically illustrating a process module according to some example embodiments, FIG. 3 is a transparent perspective view schematically illustrating a process module according to some example embodiments, FIG. 4 is an exploded perspective view schematically illustrating a process module according to some example embodiments, FIG. 5 is a cross-sectional perspective view schematically illustrating a process module according to some example embodiments, and FIG. 6 is a cross-sectional perspective view schematically illustrating a portion of a process module according to some example embodiments.

Referring to FIGS. 2 to 6, for example, each of the process modules 100a, 100b, 100c, and 100d may include a plurality of process chambers, for example, upper and lower process chambers 110 and 120, a shower head 1111, a heater block 1121, an exhaust port 1122, a rotating arm unit 1123, and a blocking slit 1124.

The upper and lower process chambers 110 and 120 may be located in different layers. The upper and lower process chambers 110 and 120 may be located to overlap or at least partially overlap each other in a plan view. Although FIG. 2 shows two process chambers, for example, the upper and lower process chambers 110 and 120, which are located (for example, arranged) vertically, inventive concepts are not limited thereto, and a plurality of process chambers may be stacked in two or more layers.

Each of the upper and lower process chambers 110 and 120 may include a processing space S in which a plurality of substrates W are processed. The plurality of substrates W may be arranged and processed in the processing space S of each of the upper and lower process chambers 110 and 120. The processing space S may or may not be physically divided and may be one internal space.

Each of the upper and lower process chambers 110 and 120 may include a processing area A in which each substrate W is arranged within the processing space S. The processing area A may be an area in which the substrate W transferred into the processing space S is arranged and may be the same as an area in which the heater block 1121, which is described below, is located. When the substrate W is transferred into the processing space S, the substrate W may be arranged in the processing area A by the rotating arm unit 1123 in each of the upper and lower process chambers 110 and 120.

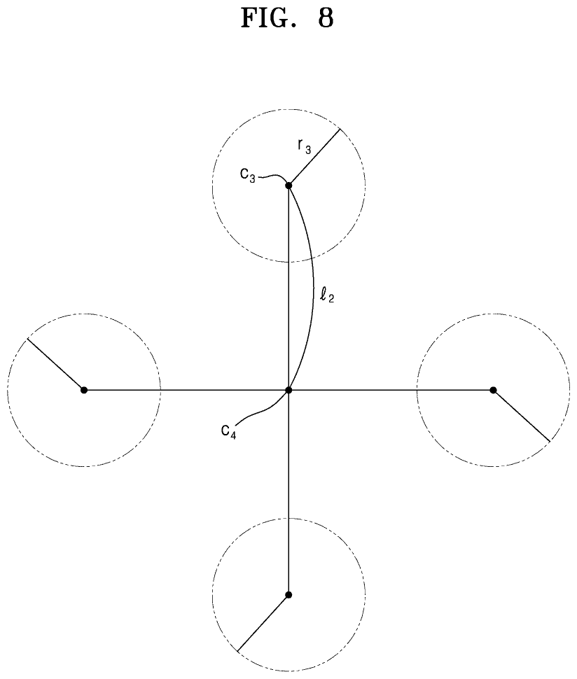

The substrate W may be, for example, a circular (for example, substantially circular) wafer, and the processing area A may have a circular shape corresponding to the shape of the substrate W, but example embodiments are not limited thereto. A distance 12 (see FIG. 8) between a first center C3 (see FIG. 8) of each of a plurality of processing areas A having a circular shape and a second center C4 (see FIG. 8), which is located at the same distance from the first center C3 of each of the processing areas A, may be, for example, at least twice a radius r3 (see FIG. 8) of each of the processing areas A, but example embodiments are not limited thereto. Because each of the processing areas A may be arranged apart from the second center C4 by at least twice the radius r3 of the processing area A, the rotating arm unit 1123 may be unobstructed when placing the substrate W on the heater block 1121. This aspect is described below.

For example, any or each of the upper and lower process chambers 110 and 120 may include a head portion 111, a heating portion 112, and an exhaust portion 113. The exhaust portion 113, the heating portion 112, and the head portion 111 may be, for example, stacked in the stated order, but example embodiments are not limited thereto. The processing space S may be formed (for example, defined) between the heating portion 112 and the head portion 111. The processing area A may be located on the heating portion 112, but example embodiments are not limited thereto.

The head portion 111 may be located on the heating portion 112 and may correspond to an upper end of each of the upper and lower process chambers 110 and 120. A plurality of shower heads 1111 may be arranged on an inner surface of the head portion 111 facing the heating portion 112. Although FIG. 3 shows four shower heads 1111, inventive concepts are not limited thereto, and at least two shower heads 1111 may be included.

The shower head 1111 may spray a process gas toward the substrate W arranged on the heater block 1121 of the heating portion 112. The shower head 1111 may include a plurality of holes (not shown) formed on (for example, defined or at least partially defined by) a surface thereof facing the substrate W and may spray the process gas uniformly onto the substrate W.

A gas line 1113 may be, for example, arranged outside the head portion 111. The process gas may flow into the shower head 1111 through the gas line 1113. A diffuser 1112 may be arranged, for example, between the gas line 1113 and the shower head 1111. The diffuser 1112 may be located in a through hole passing through (for example defined or at least partially defined by) inner and outer portions of the head portion 111. The diffuser 1112 may connect the gas line 1113 to the shower head 1111. The diffuser 1112 may allow the process gas flowing through the gas line 1113 to spread evenly or substantially evenly into the shower head 1111.

The heating portion 112 may be located between the head portion 111 and the exhaust portion 113. The heating portion 112 may include the heater block 1121. The heater block 1121 may be located to correspond to the shower head 1111.

A space formed (for example, defined or at least partially defined) between the heating portion 112 and the head portion 111 may be the processing space S. A plurality of shower heads 1111 and a plurality of heater blocks 1121 corresponding to each other may be located in the processing space S. An area in which the heater block 1121 is located may be the processing area A. One substrate W may be arranged and processed in one processing area A, bur example embodiments are not limited thereto.

The processing space S may or may not be physically divided according to the shower head 1111 and the heater block 1121 corresponding to each other. For example, a plurality of processing areas A may be located in one processing space S. Because the substrate W is arranged and processed in each of the processing areas A located in the one processing space S, productivity may be increased. In addition, because the processing space S is formed in each of the upper and lower process chambers 110 and 120 that are stacked, productivity of processing the substrate W may be further improved.

The heating portion 112 may further include, for example, a lift pin 1127 and a lift pin driver 11271. The lift pin 1127 may be located inside the heater block 1121 and may be raised or lowered through the heater block 1121. The lift pin driver 11271 may provide power to raise or lower the lift pin 1127.

In more detail, the lift pin 1127 may be moved by the lift pin driver 11271 in a direction from the heating portion 112 toward the head portion 111 (an upward direction) or in a direction from the head portion 111 toward the heating portion 112 (a downward direction) and may support the substrate W until the substrate W is mounted on the rotating arm unit 1123 or on the heater block 1121. For example, when the substrate W is transferred into the processing space S by a transfer robot 220 of the transfer module 200, the lift pin 1127 may be raised in the direction from the heating portion 112 toward the head portion 111 to support a rear surface of the substrate W on the transfer robot 220 and lift the substrate W on the transfer robot 220. In such a case, the transfer robot 220 may come out of each of the upper and lower process chambers 110 and 120. The lift pin 1127 may be lowered so that the substrate W may be arranged on the heater block 1121.

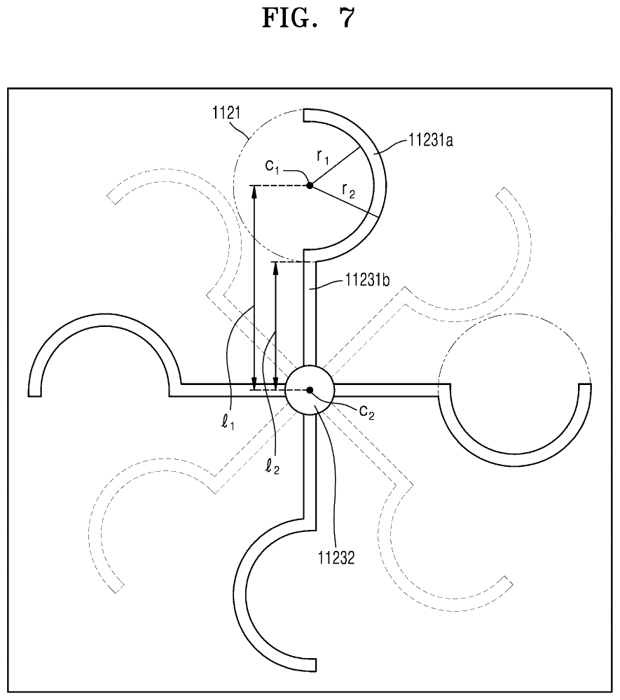

Further, while the substrate W is supported by the lift pin 1127, the rotating arm unit 1123 may rotate to be located below the substrate W, and the lift pin 1127 may be lowered so that the substrate W may be mounted on a mounting portion 11231a (see FIG. 7) of the rotating arm unit 1123. The rotating arm unit 1123 may rotate onto the heater block 1121 on which the substrate W is not arranged. After the substrate W is located on the heater block 1121, the lift pin 1127 may be raised to lift the substrate W on the mounting portion 11231a, the rotating arm unit 1123 may rotate, and then, the lift pin 1127 may be lowered to allow the substrate W to be mounted on the heater block 1121.

The heating portion 112 may further include, for example, the exhaust port 1122. The exhaust port 1122 may be, for example, formed outside the heater block 1121 and may suck in the process gas in the processing space S, but example embodiments are not limited thereto. The exhaust port 1122 may pass through the heating portion 112 from an upper surface of the heating portion 112 toward the exhaust portion 113 to be connected to a ventilation portion 1131 of the exhaust portion 113. For example, the exhaust port 1122 may be formed to surround or at least partially surround an outer periphery of the heater block 1121 in a plan view, but example embodiments are not limited thereto. When the heater block 1121 is formed in a circular or substantially circular shape, the exhaust port 1122 may be apart from the heater block 1121 by a certain distance and may be formed in a circular or substantially circular shape along the outer periphery of the heater block 1121, but example embodiments are not limited thereto.

The exhaust port 1122 may suck in the process gas in the processing space S and may discharge the process gas to the ventilation portion 1131 of the exhaust portion 113. Because the exhaust portion 113 is formed in the heater block 1121 arranged in each processing area A to suck in the process gas, mixing of process gases with each other in different processing areas A may be reduced or prevented from being.

The heating portion 112 may further include the blocking slit 1124. The blocking slit 1124 may be formed, for example, between processing areas A adjacent to each other. For example, the blocking slit 1124 may be formed between the heater blocks 1121 located in the processing areas A. The blocking slit 1124 may, for example, pass through the heating portion 112 from the upper surface of the heating portion 112 toward the exhaust portion 113 to be connected to the ventilation portion 1131 of the exhaust portion 113, but example embodiments are not limited thereto.

The blocking slit 1124 may suck in the process gas sprayed into the processing area A to prevent or hinder the process gases sprayed into different processing areas A from mixing or being mixed with each other.

In a other example embodiments, the blocking slit 1124 may eject a purge gas to prevent or hinder the process gases sprayed into different processing areas A from mixing or being mixed with each other. The ejected purge gas may be discharged to the exhaust portion 113 through the exhaust port 1122.

The rotating arm unit 1123 may be rotatably arranged in the processing space S. The rotating arm unit 1123 may receive the substrate W transferred from outside each of the upper and lower process chambers 110 and 120 and may rotate to place the substrate W on the heater block 1121. For example, the rotating arm unit 1123 may receive, from the transfer robot 220 of the transfer module 200, the substrate W transferred into the processing space S by the transfer robot 220 and may rotate to transfer the substrate W onto the heater block 1121 in the processing area A.

For example, the rotating arm unit 1123 may include a mounting arm 11231, a rotating shaft 11232, and a rotating driver 11233.

The mounting arm 11231 may receive the substrate W transferred into the processing space S by the transfer robot 220 of the transfer module 200. The mounting arm 11231 may have a smooth surface on which the substrate W may be mounted. The number of mounting arms 11231 may correspond, for example, to the number of processing areas A in the processing space S. For example, as shown in FIGS. 1 and 4, when there are four processing areas A, four mounting arms 11231 may be provided, but example embodiments are not limited thereto.

One end of the mounting arms 11231 may be connected to one end of the rotating shaft 11232. The mounting arms 11231 and the rotating shaft 11232 may be, for example, perpendicular or substantially perpendicular to each other, but example embodiments are not limited thereto. The mounting arms 11231 may rotate by rotation of the rotating shaft 11232 in a length direction thereof. For example, the mounting arms 11231 may rotate around the rotating shaft 11232. The mounting arms 11231 may be located on the processing area A by rotation of the rotating shaft 11232.

Another end of the rotating shaft 11232 may be connected to the rotating driver 11233. The rotating driver 11233 may rotate the rotating shaft 11232 about the length direction thereof as an axis. In some example embodiments, the rotating driver 11233 may rotate the rotating shaft 11232 and may also raise or lower the rotating shaft 11232 in the length direction thereof.

FIG. 7 is a plan view schematically illustrating a rotating arm unit of a process module according to some example embodiments.

Referring to FIG. 7, the mounting arm 11231 may e, for example, a mounting portion 11231a and/or a connecting portion 11231b.

The substrate W may be mounted on the mounting portion 11231a. For example, the mounting portion 11231a may have a semicircular ring shape, but example embodiments are not limited thereto. When, for example, the substrate W is a circular wafer, the semicircular ring shape of the mounting portion 11231a may allow the substrate W to be safely mounted. An inner radius r1 of the semicircular ring shape may be less than a radius of the substrate W having a circular shape, and an outer radius r2 of the semicircular ring shape may be less or greater than the radius of the substrate W having a circular shape.

The mounting portion 11231a may have a width that is narrower than a gap between the heater blocks 1121 adjacent to each other in a plan view. As described above, before the substrate W is mounted on the heater block 1121, the mounting arm 11231 may be rotated while the substrate W is supported by the lift pin 1127. For example, when the mounting arm 11231 does not overlap the heater block 1121, the lift pin 1127 may be lowered so that the substrate W may be located on the heater block 1121. Because the width of the mounting portion 11231a is formed to be less than the gap between the heater blocks 1121 adjacent to each other, even when the mounting arm 11231 is located between the heater blocks 1121 adjacent to each other, the mounting portion 11231a may not overlap the heater blocks 1121 in a plan view so that interference between the substrate W and the mounting portion 11231a as the substrate W is lowered toward the heater block 1121 may be reduced or prevented.

The connecting portion 11231b may connect one end of the rotating shaft 11232 to one end of the mounting portion 11231a. The connecting portion 11231b may extend in a straight or substantially straight line from the one end of the mounting portion 11231a having a semicircular ring shape to be connected to the one end of the rotating shaft 11232.

A distance 11 between a center c1 of the mounting portion 11231a having a semicircular ring shape and a rotational center c2 of the rotating shaft 11232 may be, for example, about at least twice an outer radius r2 of the mounting portion 11231a. In other words, a length 12 of the connecting portion 11231b may be equal to or greater than the outer radius r2 of the mounting portion 11231a.

The distance d1 between the center c1 of the mounting portion 11231a having a semicircular ring shape and the rotational center c2 of the rotating shaft 11232 is the sum or substantially equal to the sum of the outer radius r2 of the mounting portion 11231a and the length 12 of the connecting portion 11231b. While the mounting arm 11231 may need to rotate to allow the substrate W to be mounted on the heater block 1121, when the length 12 of the connecting portion 11231b is less than or substantially less than the outer radius r2 of the mounting portion 11231a having a semicircular ring shape, some interference may occur between the mounting portion 11231a and the substrate W that is lowered onto an adjacent heater block 1121.

In some inventive concepts, when the length 12 of the connecting portion 11231b is greater than or equal to the outer radius r2 of the mounting portion 11231a having a semicircular ring shape, or when the distance d1 between the center c1 of the mounting portion 11231a having a semicircular ring shape and the rotational center c2 of the rotating shaft 11232 is at least twice the outer radius r2 of the mounting portion 11231a, a distance between the heater blocks 1121 adjacent to each other may be obtained such that that even when the substrate W is lowered toward the heater block 1121, the substrate W may not come into contact or substantially into contact with the mounting portion 11231a.

FIG. 8 is a plan view schematically illustrating a processing area of a process module according to some example embodiments.

Referring to FIG. 8, the heater block 1121 may be located in the processing area A, and the heater block 1121 and the processing area A may have, for example, the same shape or size, but example embodiments are not limited thereto. For example, when the substrate W has a circular shape and the processing area A has a circular shape, the distance 12 between the first center c3 of each of the processing areas A and the second center c4, which is located at the same distance from the first center c3 of each of the processing areas A, may be at least twice the radius r3 of each of the processing areas A. The heater block 1121 may be located in the processing area A, and when the length 12 of the connecting portion 11231b is greater than or equal to the outer radius r2 of the mounting portion 11231a having a semicircular ring shape, the substrate W may be lowered and mounted on the heater block 1121 without interference with the mounting portion 11231a.

The exhaust portion 113 may be, for example, located below the heating portion 112. The exhaust portion 113 may suck in a gas, such as the process gas, in the processing space S and may discharge the gas to the outside of each of the upper and lower process chambers 110 and 120.

For example, the exhaust portion 113 may include at least one of a ventilation portion 1131 and a pumping line 1132.

The ventilation portion 1131 may be connected to the exhaust port 1122 or the blocking slit 1124 of the heating portion 112. For example, each exhaust port 1122 formed around the heater blocks 1121 and the blocking slit 1124 formed between the heater blocks 1121 may pass through the heating portion 112 to communicate (for example, be in communication with) with the ventilation portion 1131. The ventilation portion 1131 may be formed (for example, defined) as one internal space without separate division. The process gas or purge gas flowing through the exhaust portion 113 and the blocking slit 1124 may be discharged to the ventilation portion 1131.

One end of the pumping line 1132 may communicate (for example, be in communication with) with one side of the ventilation portion 1131. The pumping line 1132 may be connected to a pump (not shown), and the process gas or purge gas collected in the ventilation portion 1131 by driving the pump may be discharged to the outside of each of the upper and lower process chambers 110 and 120 through the pumping line 1132.

The transfer module 200 may be in contact with any or each of the process modules 100a, 100b, 100c, and 100d on one side thereof and may be in contact with the load lock module 300 on another side thereof. The transfer module 200 may transfer the substrate W from the load lock module 300 to any or each of the process modules 100a, 100b, 100c, and 100d or may transfer the substrate W from each of the process modules 100a, 100b, 100c, and 100d to the load lock module 300.

For example, the transfer module 200 may include, for example, a transfer chamber 210 and the transfer robot 220.

The transfer chamber 210 may have, for example, a polygonal shape in a plan view. The load lock module 300 and the process modules 100a, 100b, 100c, and 100d may be arranged at respective edges of the transfer chamber 210. The load lock module 300 may be arranged at an edge closest to the equipment front end module 400, among the edges of the transfer chamber 210, but example embodiments are not limited thereto.

For example, as shown in FIG. 1A, the transfer chamber 210 may have a pentagonal shape in a plan view. The transfer chamber 210 may have five, for example, edges. Four process modules 100a, 100b, 100c, and 100d and one load lock module 300 may be arranged at respective edges. However, the shape of the transfer chamber 210 and the number of each of the process modules 100a, 100b, 100c, and 100d and the load lock module 300, which are arranged adjacent to the transfer chamber 210, are not limited thereto, and may be changed.

The transfer robot 220 may include an upper transfer robot 221 and a lower transfer robot 222. The upper transfer robot 221 may include a plurality of transfer arms, for example, first and second upper transfer arms 221a and 221b, and the lower transfer robot 222 may include a plurality of transfer arms, for example, first and second lower transfer arms 222a and 222b. Any or each of the first and second upper transfer arms 221a and 221b and the first and second lower transfer arms and 222a and 222b may transfer the substrate W. Each of the first and second upper transfer arms 221a and 221b and the first and second lower transfer arms and 222a and 222b may unload the substrate W stored in the load lock module 300. Subsequently, each of the first and second upper transfer arms 221a and 221b and the first and second lower transfer arms and 222a and 222b may grasp the substrate W and may transfer the substrate W to each of the process modules 100a, 100b, 100c, and 100d.

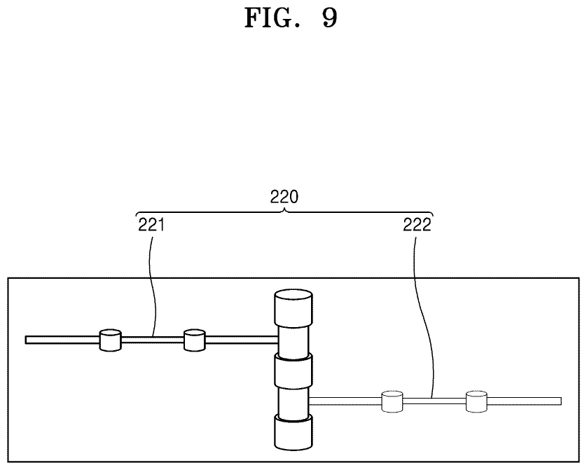

When each of the process modules 100a, 100b, 100c, and 100d has the upper and lower process chambers 110 and 120 that are stacked, the transfer robot 220 may be provided to correspond to each of the upper and lower process chambers 110 and 120 that are stacked. Referring to FIG. 9, when the upper and lower process chambers 110 and 120 are stacked vertically as shown in FIG. 2, the transfer robot 220 may include the upper transfer robot 221 corresponding to the upper process chamber 110 and the lower transfer robot 222 corresponding to the lower process chamber 120. However, inventive concepts are not limited thereto, and when process chambers are stacked in three or more layers, three or more transfer robots may also be vertically stacked to respectively correspond to the stacked process chambers.

The load lock module 300 may be arranged, for example, between the transfer module 200 and the equipment front end module 400. The load lock module 300 may provide (for example, define or at least partially define) a space to temporarily store the substrates W brought in or taken out of the process modules 100a, 100b, 100c, and 100d. For example, the load lock module 300 may be a space in which the substrates W brought in or taken out of the process modules 100a, 100b, 100c, and 100d temporarily stay.

The interior of the load lock module 300 may be switchable to (for example, configured to operate with respect to) vacuum and atmospheric pressure. Accordingly, the interior of each of the transfer module 200 and the process modules 100a, 100b, 100c, and 100d may be maintained at vacuum, and the interior of the equipment front end module 400 may be maintained at atmospheric pressure.

A first gate valve (not shown) may be installed between the load lock module 300 and the equipment front end module 400. A second gate valve (not shown) may be installed between the load lock module 300 and the transfer module 200. Only one of the first gate valve and the second gate valve may be open so that the interior of each of the transfer module 200 and the process modules 100a, 100b, 100c, and 100d may be maintained at vacuum.

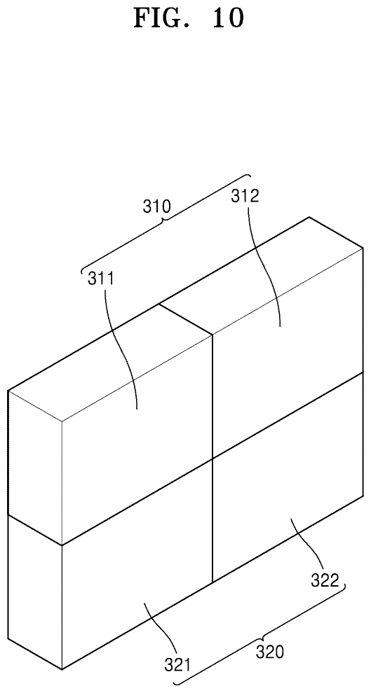

When, for example, each of the process modules 100a, 100b, 100c, and 100d has the upper and lower process chambers 110 and 120 that are stacked, the load lock module 300 may include upper and lower load lock chambers 310 and 320, which are stacked and respectively correspond to the upper and lower process chambers 110 and 120 that are stacked. Referring to FIG. 10, when the upper and lower process chambers 110 and 120 are stacked vertically as shown in FIG. 2, the load lock module 300 may include the upper load lock chamber 310 corresponding to the upper process chamber 110 and the lower load lock chamber 320 corresponding to the lower process chamber 120.

Further, the upper load lock chamber 310 may include, for example, a first upper sub load lock chamber 311 and a second upper sub load lock chamber 312. The first upper sub load lock chamber 311 and the second upper sub load lock chamber 312 may be located in the same layer within the upper load lock chamber 310, but example embodiments are not limited thereto.

The lower load lock chamber 320 may also include a first lower sub load lock chamber 321 and a second lower sub load lock chamber 322. The first lower sub load lock chamber 321 and the second lower sub load lock chamber 322 may be located in the same layer within the lower load lock chamber 320, but example embodiments are not limited thereto.

The first upper sub load lock chamber 311 and the second upper sub load lock chamber 312 may respectively correspond to the first upper transfer arm 221a and the second upper transfer arm 221b of the upper transfer robot 221. For example, the first upper transfer arm 221a of the upper transfer robot 221 may load or unload the substrate W of the first upper sub load lock chamber 311, and the second upper transfer arm 221b of the upper transfer robot 221 may load or unload the substrate W of the second upper sub load lock chamber 312.

The first lower sub load lock chamber 321 and the second lower sub load lock chamber 322 may respectively correspond to the first lower transfer arm 222a and the second lower transfer arm 222b of the lower transfer robot 222. For example, the first lower transfer arm 222a of the lower transfer robot 222 may load or unload the substrate W of the first lower sub load lock chamber 321, and the second lower transfer arm 222b of the lower transfer robot 222 may load or unload the substrate W of the second lower sub load lock chamber 322.

However, inventive concepts are not limited thereto, and when process chambers are stacked in, for example, three or more layers, three or more load lock chambers may also be vertically stacked to respectively correspond to the stacked process chambers.

In some inventive concepts, because a plurality of transfer robots simultaneously load or unload substrates in correspondence to a plurality of stacked process chambers and a plurality of stacked load lock chambers, a substrate processing time may be shortened.

The equipment front end module 400 may be arranged between the load lock module 300 and the load port 500. The equipment front end module 400 may transfer the substrate W between the load port 500 and the load lock module 300. Each load port 500 may provide (for example, define) a space in which a container FOUP containing the substrate W is placed. The equipment front end module 400 may include a transfer robot 420. The transfer robot 420 may take out the substrate W yet to be processed from the container FOUP placed in the load port 500 and may transfer the substrate W to the load lock module 300. In addition, the transfer robot 420 may transfer the substrate W processed in each of the process modules 100a, 100b, 100c, and 100d into the container FOUP from the load lock module 300.

While inventive concepts have been particularly shown and described with reference to example embodiments thereof, it will be understood that various changes in form and details may be made therein without departing from the spirit and scope of the following claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

What is claimed is:

1. A substrate processing apparatus comprising:
a process module processing a plurality of substrates,
wherein the process module comprises:
a plurality of process chambers, each process chamber configured to process the plurality of substrates in a processing space defined thereby;
a plurality of processing areas within each processing space, each processing area configured to have at least one substrate of the plurality of substrates arranged thereon;
a heater block in each processing area, each heater block configured to have at least one substrate of the plurality of substrates arranged thereon;
a shower head on each heater block, each shower head configured to spray a process gas onto at least one of the plurality of substrates;
a rotating arm unit configured to receive each substrate from an outside of the process chambers and to rotate to place each substrate on each heater block; and
an exhaust port outside of each heater block and configured to suck in the process gas,
wherein the process chambers are individually located in different layers.

2. The substrate processing apparatus of claim 1, wherein the process chambers located in different layers at least partially overlap with each other in a plan view.

3. The substrate processing apparatus of claim 1, wherein, when each substrate has a circular shape and each processing area has a circular shape, a distance between a first center of each processing area and a second center is greater than twice a radius of each processing area, the second center being equidistant to the first center of each processing area.

4. The substrate processing apparatus of claim 1, wherein the rotating arm unit comprises
at least one mounting arm, each mounting arm configured to have each substrate placed thereon
a rotating shaft coupled to one end of the at least one mounting arm; and
a rotating driver configured to rotate the rotating shaft about a length direction of the rotating shaft as an axis.

5. The substrate processing apparatus of claim 4, wherein the at least one mounting arm comprises
a mounting portion configured the have each substrate mounted thereon; and
a connecting portion connecting one end of the rotating shaft to one end of the mounting portion,
wherein the mounting portion has a width that is narrower than a gap defined between adjacent heater blocks in a plan view.

6. The substrate processing apparatus of claim 5, wherein, when each substrate has a circular shape, the mounting portion has a semicircular ring shape, an inner radius of the semicircular ring shape being less than a radius of each substrate, and
a distance between a center of the semicircular ring shape and a rotational center of the rotating shaft is at least twice an outer radius of the semicircular ring shape.

7. The substrate processing apparatus of claim 1, wherein the exhaust port surrounds an outer periphery of each heater block in a plan view.

8. The substrate processing apparatus of claim 1, further comprising:
at least one blocking slit between adjacent processing areas of the plurality of processing areas.

9. The substrate processing apparatus of claim 8, wherein the at least one blocking slit is configured to suck in the process gas such that process gases sprayed into different processing areas do not mix with each other.

10. The substrate processing apparatus of claim 8, wherein the at least one blocking slit is configured to eject a purge gas such that process gases sprayed into different processing areas do not mix with each other.

11. A substrate processing apparatus comprising:
A plurality of process modules each comprising a plurality of process chambers, the process chambers arranged in different layers;
a transfer module configured to transfer a substrate to and from each process module;
a load lock module arranged on one side of the transfer module and configured to receive the substrate transferred to or from the transfer module;
an equipment front end module arranged on one side of the load lock module and configured to keep the substrate on standby; and
a load port arranged on one side of the equipment front end module and configured to be loaded with the substrate,
wherein the process modules are located around the transfer module and in contact with the transfer module,
each process chamber is configured to process a plurality of substrates in a processing space defined therein, and
a plurality of processing areas is located within each processing space, each processing area configured to have at least one substrate of the plurality of substrates arranged therein.

12. The substrate processing apparatus of claim 11, wherein each process module further comprises:
a heater block in each of the plurality of processing areas, each heater block configured to have at least one of the plurality of substrates are arranged thereon;
a shower head on each heater block, each shower head configured to spray a process gas onto at least one substrate;
a rotating arm unit configured to receive each substrate from an outside the process chambers and configured to rotate to place each substrate on each heater block; and
an exhaust port formed outside each heater block and configured to suck in the process gas,
wherein each processing module is configured to have a blocking gas sprayed between ones of the plurality of processing areas such that process gases in different processing areas do not mix with each other.

13. The substrate processing apparatus of claim 12, wherein when each substrate has a circular shape and each processing area has a circular shape, a distance between a first center of each processing area and a second center is greater than twice a radius of each processing area, the second center being equidistant from the first center of each processing area.

14. The substrate processing apparatus of claim 12, wherein the rotating arm unit comprises:
at least one mounting arm, the at least one mounting arm configured to have each substrate placed thereon;
a rotating shaft coupled to one end of the at least one mounting arm; and
a rotating driver configured to rotate the rotating shaft about a length direction of the rotating shaft as an axis,
wherein the at least one mounting arm comprises
a mounting portion configured to have each substrate mounted thereon;
a connecting portion connecting one end of the rotating shaft to one end of the mounting portion, and
the mounting portion has a width that is narrower than a gap defined between adjacent heater blocks in a plan view.

15. The substrate processing apparatus of claim 14, wherein, when each substrate has a circular shape, the mounting portion has a semicircular ring shape, an inner radius of the semicircular ring shape being less than a radius of each substrate, and
a distance between a center of the semicircular ring shape and a rotational center of the rotating shaft is at least twice an outer radius of the semicircular ring shape.

16. A substrate processing apparatus comprising:
a plurality of process modules, each process module comprising a plurality of process chambers arranged in different layers, each process chamber configured to process a plurality of substrates in a processing space defined thereby;
a transfer module configured to transfer each substrate to or from each process module;
a load lock module arranged on one side of the transfer module and configured to receive each substrate transferred to or from the transfer module;
an equipment front end module arranged on one side of the load lock module and configured to keep each substrate on standby; and
a load port arranged on one side of the equipment front end module and configured to have each substrate loaded therein;
wherein each process chamber further comprises
a head portion comprising a shower head configured to spray a process gas onto at least one substrate;
a heating portion comprising a heater block and arranged in a processing area, the processing area configured to have ones of the plurality of substrates processed therein; and
an exhaust portion on an outer periphery of the heater block and comprising an exhaust port configured to discharge the process gas,
the processing space of each process chamber is defined between the head portion and the heating portion thereof, and
a plurality of processing areas is located within each processing space.

17. The substrate processing apparatus of claim 16, further comprising a blocking slit between adjacent processing areas of the plurality of processing areas.

18. The substrate processing apparatus of claim 17, wherein the blocking slit is configured to suck in the process gas such that process gases sprayed into different processing areas do not mix with each other.

19. The substrate processing apparatus of claim 17, wherein the blocking slit is configured to eject a purge gas such that process gases sprayed into different processing areas do not mix with each other.

20. The substrate processing apparatus of claim 16, wherein, when each substrate has a circular shape and each processing area has a circular shape, a distance between a first center of each processing area and a second center is at least twice a radius of each processing area, the second center being equidistant from the first center of each processing area.
